(19) United States
(12) Patent Application Publication
(10) Pub. No.: US 2018/0277406 A1
(43) Pub. Date: Sep. 27, 2018

(54) SUBSTRATE TREATMENT APPARATUS AND MANUFACTURING METHOD OF SEMICONDUCTOR DEVICE

(71) Applicant: TOSHIBA MEMORY CORPORATION, Minato-ku (JP)

(72) Inventors: Koji NAKAHARA, Inabe (JP); Tomohisa IINO, Yokkaichi (JP); Ryota FUJITSUKA, Yokkaichi (JP)

(73) Assignee: TOSHIBA MEMORY CORPORATION, Minato-ku (JP)

(21) Appl. No.: 15/699,727

(22) Filed: Sep. 8, 2017

(30) Foreign Application Priority Data
Mar. 23, 2017 (JP) 2017-058104

(51) Int. Cl. H01L 21/67; H01L 21/673

(52) U.S. Cl. CPC H01L 21/67207; H01L 21/67017; H01L 21/67253; H01L 21/67346

(57) ABSTRACT

According to an embodiment, a substrate treatment apparatus includes a vacuum chamber, a cylindrical member, a gas feed member, a support member and a plurality of plate members. The cylindrical member is disposed in the vacuum chamber and includes a gas outlet. The support member supports a plurality of treated substrates in a stacked state in the cylindrical member. The plurality of plate members are supported on the support member and include a patterned surface or an outer circumferential part outside the treated substrate.

### CROSS-REFERENCE TO RELATED APPLICATIONS

This application is based upon and claims the benefit of priority from Japanese Patent Application No. 2017-058104, filed on Mar. 23, 2017; the entire contents of which are incorporated herein by reference.

### FIELD

Embodiments of the present invention relate to a substrate treatment apparatus and a manufacturing method of a semiconductor device.

### BACKGROUND

In a film forming step for semiconductor devices, for example, process gas is simultaneously fed to a plurality of substrates housed in a vacuum chamber to form a film on each substrate. A substrate treatment apparatus used in such a film forming step includes, for example, a gas feed member including a plurality of gas feed ports, a cylindrical member housing a plurality of substrates, and the like in order to make flows of gas uniform between the plurality of substrates.

However, when a pattern of the aforementioned film becomes complex and the surface area of the substrate becomes large, there is supposed a case where a gas concentration is nonuniform in the cylindrical member. In such a case, film thicknesses tend to vary between a plurality of substrates.

According to embodiments of the present invention, there are provided a substrate treatment apparatus and a manufacturing method of a semiconductor device capable of suppressing variation in film thickness between a plurality of substrates.

### BRIEF DESCRIPTION OF THE DRAWINGS

FIG. 1 is a cross-sectional view of a substrate treatment apparatus according to a first embodiment;

FIG. 2 is a plan view of a cylindrical member;

FIG. 3 is a plan view of a plate member 50 according to the first embodiment;

FIG. 4A is a cross-sectional view of the plate member including a pattern film;

FIG. 4B is a cross-sectional view of the plate member including a pattern groove;

FIG. 5 is a cross-sectional view of a treated substrate;

FIG. 6 is a cross-sectional view of a substrate treatment apparatus according to a second embodiment;

FIG. 7 is a cross-sectional view of a substrate treatment apparatus according to a third embodiment;

FIG. 8 is a perspective view of a cylindrical member according to the third embodiment as seen from a gas inlet side; and

FIG. 9 is a perspective view of a cylindrical member according to a modification of the third embodiment as seen from a gas outlet side.

### DETAILED DESCRIPTION

Embodiments will now be explained with reference to the accompanying drawings. The present invention is not limited to the embodiments.

### First Embodiment

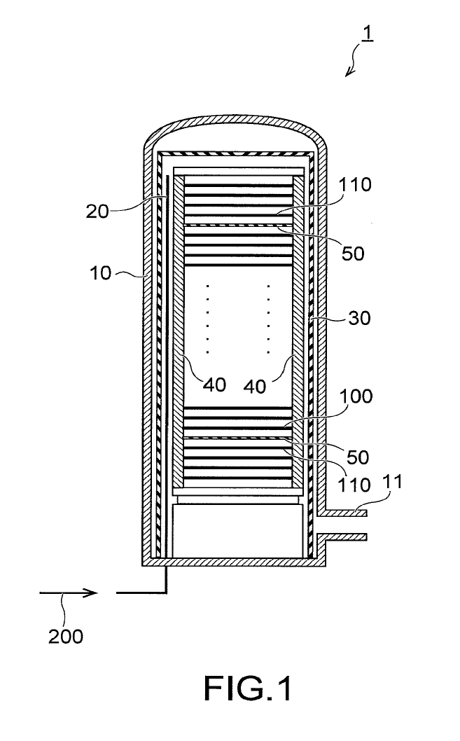

FIG. 1 is a cross-sectional view of a substrate treatment apparatus according to a first embodiment. A substrate treatment apparatus 1 according to the present embodiment is an ALD (Atomic Layer Deposition) film forming device. Specifically, the substrate treatment apparatus 1 includes a vacuum chamber 10, a gas feed member 20, a cylindrical member 30, a support member 40 and plate members 50.

The vacuum chamber 10 houses the gas feed member 20 and the cylindrical member 30. Moreover, the vacuum chamber 10 includes a discharge port 11.

The gas feed member 20 ejects process gas 200 inside the cylindrical member 30. The process gas 200 houses a material for films formed on a plurality of treated substrates 100.

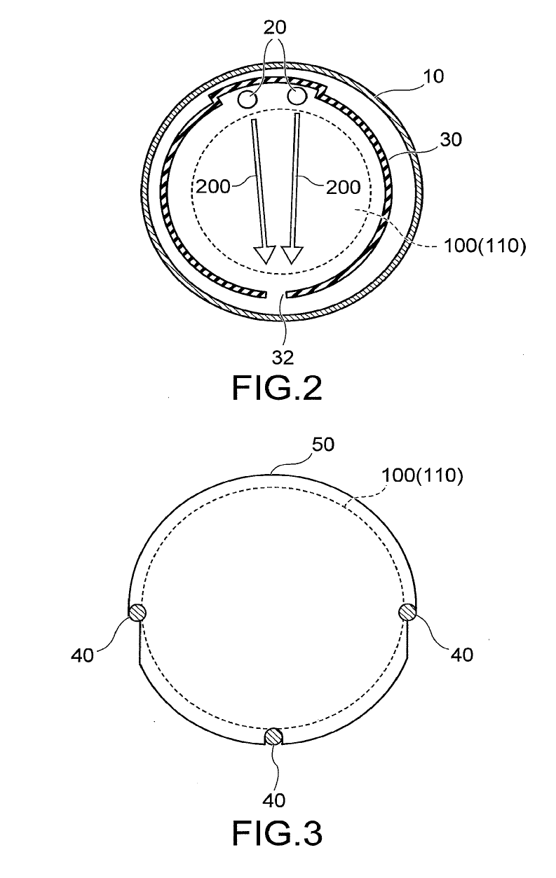

FIG. 2 is a plan view of the cylindrical member 30. The cylindrical member 30 includes a gas outlet 32 opposite to the gas feed member 20. The gas outlet 32 is formed, for example, into a slit shape extending in the vertical direction. The process gas 200 discharged from the gas feed member 20 flows out from the gas outlet 32. With this cylindrical member 30, flows of the process gas 200 between the plurality of treated substrates 100 are held to be uniform to some extent.

Returning to FIG. 1, the support member 40 supports the plurality of treated substrates 100, a plurality of dummy substrates 110 and the plurality of plate members 50. The plurality of treated substrates 100 and the plurality of dummy substrates 110 are supported on the support member 40 in the state where they are stacked. The dummy substrates 110 are supported on the support member 40 above the uppermost treated substrate 100 and below the lowermost treated substrate 100. With the dummy substrates 110, a temperature in the cylindrical member 30 is maintained to be uniform to some extent.

As shown in FIG. 1, the plate members 50 are disposed between the uppermost treated substrate 100 and the dummy substrate 110 and between the lowermost treated substrate 100 and the dummy substrate 110. In other words, the plate members 50 are supported on the support member 40 at positions where they sandwich the plurality of treated substrates 100.

FIG. 3 is a plan view of the plate member 50. As shown in FIG. 3, the support member 40 includes triangularly arranged three support columns. The plate member 50 is supported by grooves (not shown) formed in the support columns on the support member 40. Moreover, the treated substrates 100 and the dummy substrates 110 are also supported on the support member 40 in the similar modes.

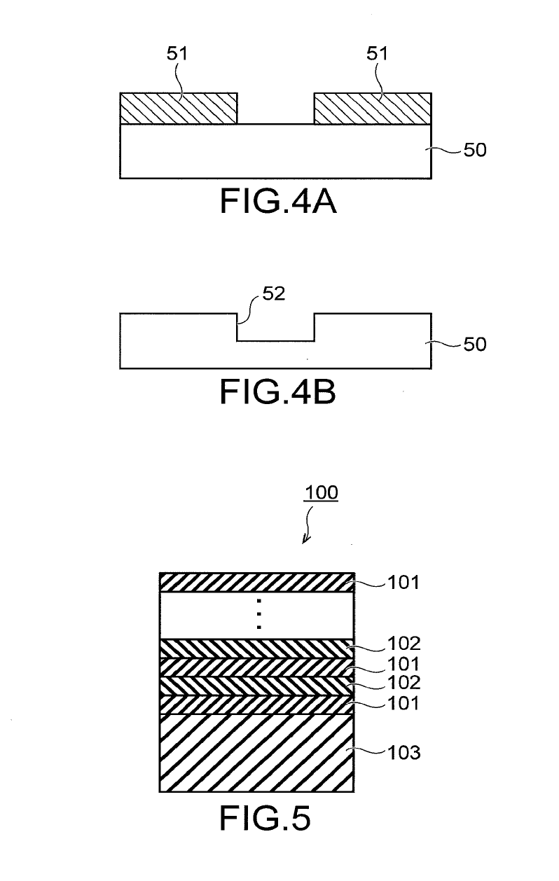

FIG. 4A is a cross-sectional view of the plate member 50 that includes a pattern film. FIG. 4B is a cross-sectional view of the plate member 50 that includes a pattern groove. The plate member 50 is formed, for example, using quartz, silicon carbide (SiC) or silicon.

A pattern film 51 shown in FIG. 4A is formed on the surface of the plate member 50 by a film forming method such as sputtering. On the other hand, a pattern groove 52 shown in FIG. 4B is formed on the surface of the plate member 50 by a method such as etching. When the pattern film 51 or the pattern groove 52 is formed, the surface area of the plate member 50 increases. In this case, the surface area of the plate member 50 is desirably equivalent to the surface area of the treated substrate 100 in order to prevent a concentration of the process gas 200 from being nonuniform. For example, when a three-dimensional memory including memory cells stacked is formed on the treated substrate 100, the shape of the pattern film 51 is desirably the same shape as that of a film formed on the surface of the treated substrate 100. Likewise, when a plurality of holes are formed on the surface of the treated substrate 100, the shape of the pattern groove 52 is desirably the same shape as that of the holes.

FIG. 5 is a cross-sectional view of the treated substrate 100. In the present embodiment, by using the aforementioned substrate treatment apparatus 1, silicon oxide films (SiO₂) 101 and silicon nitride films (SiN) 102 are alternately formed on a silicon substrate 103. Hereafter, these film forming steps are briefly described.

As shown in FIG. 1, after the support member 40 supporting the plate members 50, the treated substrates 100 and the dummy substrates 110 is transported into the cylindrical member 30, the process gas 200 housing the material of the silicon oxide film 101 is fed into the cylindrical member 30 from the gas feed member 20. As a result, the silicon oxide films 101 are formed on the treated substrates 100. After that, this process gas 200 flows out of the cylindrical member 30, and is discharged from the discharge port 11 of the vacuum chamber 10 to the outside, for example, by a pump.

Next, the process gas 200 housing the material of the silicon nitride film 102 is similarly fed into the cylindrical member 30 from the gas feed member 20. This process gas 200 forms the silicon nitride films 102 on the silicon oxide films 101. As above, a plurality of kinds of the process gas 200 are alternately fed to form stacked films including the silicon oxide films 101 and the silicon nitride films 102 alternately stacked.

When film forming is performed using the process gas 200, consumption amounts of the process gas 200 are different between the treated substrate 100 and the dummy substrate 110 since the surface area of the dummy substrate 110 is smaller than the surface area of the treated substrate 100. As a result, a gas concentration becomes nonuniform at a boundary between an arrangement area of the treated substrates 100 and an arrangement area of the dummy substrates 110. If the substrate treatment apparatus 1 is supposed to include no plate members 50, the process gas 200 is to come into the arrangement area of the treated substrates 100. As a result, film thicknesses tend to vary between the plurality of treated substrates 100.

Nevertheless, in the present embodiment, the plate members 50 are disposed at boundaries between the arrangement area of the dummy substrates 110 and the arrangement area of the treated substrates 100. Moreover, the pattern film 51 or the pattern groove 52 is on the surface of the plate member 50. Therefore, the surface area of the plate member 50 is equivalent to the surface area of the treated substrate 100. As a result, the treated substrates 100 are hardly affected by a concentration difference in the process gas 200. Accordingly, variation in film thickness between the plurality of treated substrates 100 can be suppressed.

Notably, a film formed on the treated substrate 100 is not limited to the stacked film including the silicon oxide films 101 and the silicon nitride films 102 alternately stacked. For example, it may be a metal film. Therefore, in the present embodiment, a plurality of plate members 50 different in shape of the pattern film 51 or the pattern groove 52 are desirably prepared. In this case, the optimum plate member 50, that is, the plate member 50 including the surface area equivalent to that of the treated substrate 100 can be selected depending on the pattern of a film formed on the treated substrate 100.

### Second Embodiment

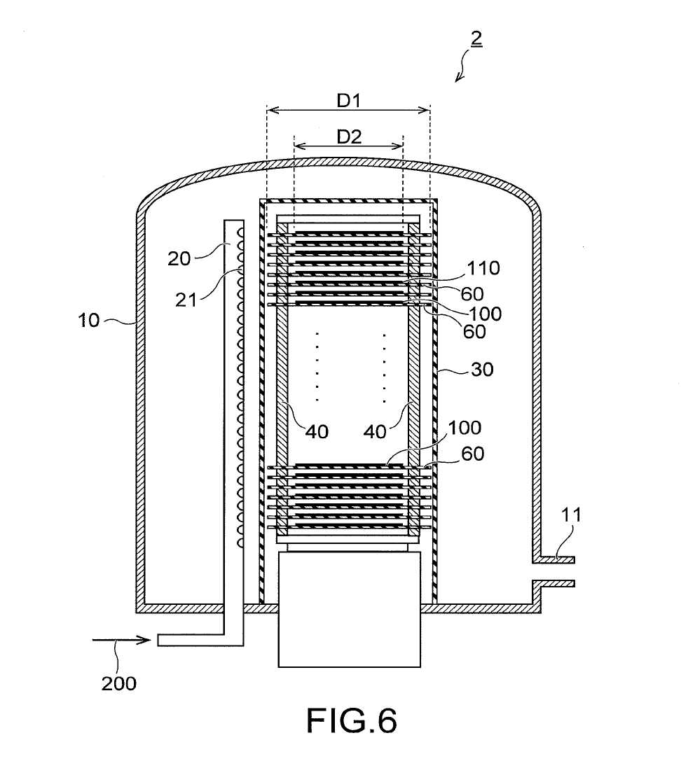

FIG. 6 is a cross-sectional view of a substrate treatment apparatus according to a second embodiment. Herein, the similar constituents similar to those in the first embodiment are given the same signs, and their detailed description is omitted.

A substrate treatment apparatus 2 according to the present embodiment is different from the first embodiment in including a plurality of plate members 60 in place of the plurality of plate members 50. The plurality of plate members 60 are supported on the support member 40 in the state where they are arranged along a plurality of gas feed ports 21. On the plurality of plate members 60, the plurality of treated substrates 100 and the plurality of dummy substrates 110 are respectively placed.

As shown in FIG. 6, each plate member 60 includes an outer circumferential part outside each of the treated substrates 100 and the dummy substrates 110. In other words, an outer diameter D1 of each plate member 60 is larger than an outer diameter D2 of each of the treated substrates 100 and the dummy substrates 110. Similarly to the plate members 50, the plate members 60 are also formed, for example, using quartz or silicon carbide (SiC). Notably, the pattern film 51 and the pattern groove 52 described for the first embodiment may be formed on the surfaces of the plate members 60, or may not be formed thereon.

Also in the film forming step using the aforementioned substrate treatment apparatus 2, the process gas 200 is simultaneously fed to the plurality of treated substrates 100 from the plurality of gas feed ports 21. In this stage, a difference in surface area between the dummy substrate 110 and the treated substrate 100 can cause a concentration difference in the process gas 200 between the arrangement area of the dummy substrates 110 and the arrangement area of the treated substrates 100. In this case, there is a concern that the process gas 200 comes into the arrangement area of the treated substrates 100, which causes variation in film thickness between the plurality of treated substrates 100.

Nevertheless, in the present embodiment, the plurality of plate members 60 are disposed between the treated substrates 100 and between the dummy substrates 110. Namely, spaces between the substrates are partitioned by the plate members 50. Therefore, the process gas 200 hardly comes thereinto. Hence, the process gas 200 is uniformly fed to the plurality of plate members 60. As a result, variation in film thickness can be suppressed. Notably, while in the present embodiment, the gas feed member 20 is installed outside the cylindrical member 30, it may be installed inside the cylindrical member 30.

### Third Embodiment

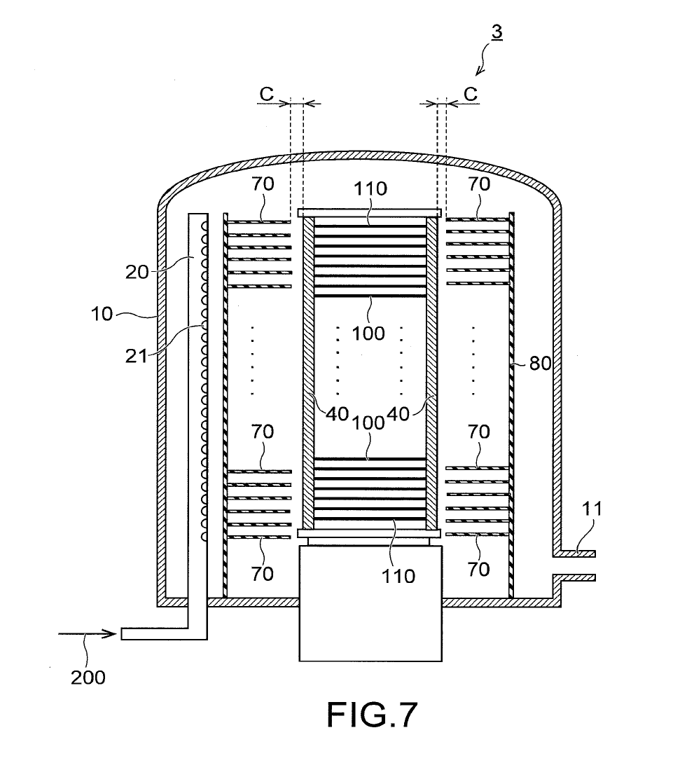

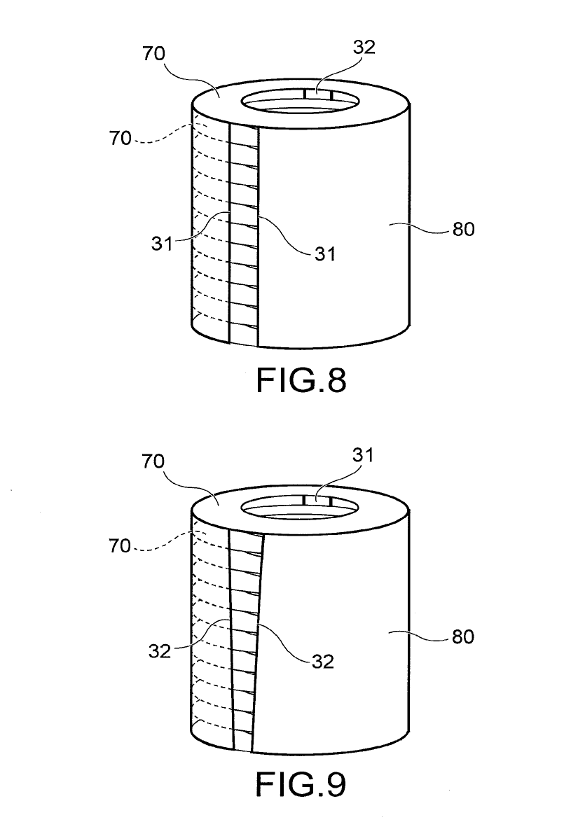

FIG. 7 is a cross-sectional view of a substrate treatment apparatus according to a third embodiment. FIG. 8 is a perspective view of a cylindrical member 80 according to the third embodiment as seen from a gas inlet 31 side. FIG. 8 perspectively shows a part inside the cylindrical member 80. In FIG. 7 and FIG. 8, the similar constituents to those in the second embodiment are given the same signs, and their detailed description is omitted.

A substrate treatment apparatus 3 according to the present embodiment is different from the first embodiment in including a plurality of annular members 70 in place of the plurality of plate members 50. As shown in FIG. 7, the plurality of annular members 70 are disposed on the inner surface of the cylindrical member 80 along the plurality of gas feed ports 21. Moreover, the plurality of annular members 70 enclose the support member 40. The annular member 70 is formed using the same material as that of the cylindrical member 80, such, for example, as quartz. Notably, on the surfaces of the annular members 70, the pattern film 51 and the pattern groove 52 described for the first embodiment may be formed, or may not be formed.

Also in the film forming step using the aforementioned substrate treatment apparatus 3, the process gas 200 fed from the plurality of gas feed ports 21 flows into the cylindrical member 80 from the gas inlet 31. This process gas 200 passes between the plurality of treated substrates 100 and between the plurality of dummy substrates 110, and after that, flows out of the gas outlet 32.

In the cylindrical member 80, due to the difference in surface area between the dummy substrate 110 and the treated substrate 100, the concentration difference in process gas 200 can arise between the arrangement area of the dummy substrates 110 and the arrangement area of the treated substrates 100. In this case, there is a concern that the process gas 200 comes into the arrangement area of the treated substrates 100 from the outside of the support member 40.

Nevertheless, in the present embodiment, the plurality of annular members 70 are disposed outside the support member 40. The annular members 70 shut channels of the process gas 200 through which the process gas 200 comes into the arrangement area of the treated substrates 100 from the outside of the support member 40. Accordingly, since the process gas 200 is uniformly fed to the plurality of annular members 70, variation in film thickness can be suppressed.

As shown in FIG. 8, in the present embodiment, the cylindrical member 80 includes the gas inlet 31 which is slit-shaped. The area of the gas inlet 31 is larger than the area of the plurality of gas feed ports 21. Therefore, the process gas 200 easily flows into the gas inlet 31 from the plurality of gas feed ports 21. As a result, efficiency of use of the process gas 200 can be enhanced.

Notably, in the present embodiment, if a clearance C between the support member 40 and the annular members 70 is large, the annular members 70 cannot sufficiently prevent the process gas 200 from the coming-into. Therefore, this clearance C is desirably as small as possible not to prevent elevation movement or rotation movement of the support member 40.

(Modification)

FIG. 9 is a perspective view of the cylindrical member 80 according to a modification of the third embodiment as seen from the gas outlet 32 side. FIG. 9 perspectively shows a part inside the cylindrical member 80.

As shown in FIG. 9, the cylindrical member 80 includes the slit-shaped gas outlet 32. As shown in FIG. 7, the cylindrical member 80 is disposed in the vacuum chamber 10. The discharge port 11 is formed in a lower part on the lateral surface of the vacuum chamber 10. As a result, while a lower part of the gas outlet 32 is positioned close to the discharge port 11, an upper part of the gas outlet 32 is separate from the discharge port 11. Therefore, there is a high possibility that discharge amounts of the process gas 200 are nonuniform with respect to the upper part and the lower part of the gas outlet 32 when as to the shape of the gas outlet 32, for example, these parts of the gas outlet 32 have the same areas.

Therefore, in the present modification, the area of the gas outlet 32 becomes larger as going from the lower part toward the upper part. Namely, the area of the gas outlet 32 becomes larger as going separate from the discharge port 11. Thereby, nonuniform discharge of the process gas 200 can be prevented. Notably, the present modification can also be applied to the first embodiment and the second embodiment as well as to the third embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A substrate treatment apparatus comprising:
a vacuum chamber;
a cylindrical member disposed in the vacuum chamber and including a gas outlet;
a gas feed member disposed in the vacuum chamber or the cylindrical member;
a support member to support a plurality of treated substrates in a stacked state in the cylindrical member; and
a plurality of plate members supported on the support member and including a patterned surface or an outer circumferential part outside the treated substrate.

2. The substrate treatment apparatus according to claim 1, wherein
the plurality of plate members include the patterned surface, and are supported on the support member at positions where the plurality of plate members sandwich the plurality of treated substrates.

3. The substrate treatment apparatus according to claim 1, wherein
the plurality of plate members include the outer circumferential part, and the plurality of treated substrates are respectively placed on the plurality of plate members.

4. A substrate treatment apparatus comprising:
a vacuum chamber;
a gas feed member including a plurality of gas feed ports disposed in the vacuum chamber;
a cylindrical member disposed in the vacuum chamber and including a gas inlet and a gas outlet;
a support member to support a plurality of treated substrates disposed in the cylindrical member along the plurality of gas feed ports; and
an annular member disposed on an inner surface of the cylindrical member along the plurality of gas feed ports and enclosing the support member.

5. The substrate treatment apparatus according to claim 4, wherein
the vacuum chamber includes a discharge port, and
an area of the gas outlet is larger as going separate from the discharge port, and an area of the gas inlet is larger than an area of the plurality of gas feed ports.

6. A manufacturing method of a semiconductor device using a vacuum chamber, a cylindrical member disposed in the vacuum chamber and including a gas outlet, and a gas feed member disposed in the cylindrical member, the method comprising:
disposing, in the cylindrical member, a support member supporting a plurality of treated substrates in a stacked state and supporting plate members including a patterned surface at positions where the plate members sandwich the plurality of treated substrates; and
feeding process gas for treating the plurality of treated substrates from the gas feed member, and after that, discharging the process gas from the gas outlet to an outside of the vacuum chamber.

7. The manufacturing method of a semiconductor device according to claim 6, wherein
the support member also supports dummy substrates of including which a surface area is smaller than that of the treated substrate, and
the plurality of plate members are disposed between the treated substrates and the dummy substrates.

8. The manufacturing method of a semiconductor device according to claim 6, wherein
a plurality of kinds of the process gas are alternately fed to alternately form silicon oxide films and silicon nitride films simultaneously on the plurality of treated substrates.
